(19) United States
(12) Patent Application Publication
(10) Pub. No.: US 2008/0116574 A1
(43) Pub. Date: May 22, 2008

(54) BGA package with encapsulation on bottom of substrate

(75) Inventor: Wen-Jeng Fan, Hsinchu (TW)

Correspondence Address: TROXELL LAW OFFICE PLLC, SUITE 1404, 5205 LEESBURG PIKE, FALLS CHURCH, VA, 22041, US

(73) Assignee: POWERTECH TECHNOLOGY INC.

(21) Appl. No.: 11/600,916

(22) Filed: Nov. 17, 2006

(51) Int. Cl. H01L 23/48

(52) U.S. Cl. 257/738; 257/E23.01; 257/E23.015

(57) ABSTRACT

A BGA package with encapsulation on substrate bottom comprises a chip, a substrate, a molding compound and a plurality of solder balls. The substrate has a SMT surface placing a plurality of ball pads. The molding compound encapsulates a solder resist layer on the SMT surface of the substrate and has a plurality of through holes exposing the ball pads respectively. The hole diameter of the through holes is greater than that of the openings of the solder resist layer on the substrate to allow the solder balls not to contact the molding compound. The solder balls are disposed in the through holes and are bonded to the exposed ball pads of the substrate thereby enhancing moisture resistance of BGA products and preventing the solder balls from falling because of contact stress of the molding compound.

### FIELD OF THE INVENTION

The present invention relates generally to a semiconductor package, and more specifically to a BGA (Ball Grid Array) package with encapsulation on bottom of substrate for enhancing product reliability by improving moisture resistance.

### BACKGROUND OF THE INVENTION

A BGA package is one kind of semiconductor package design that has a plurality of solder balls arranged in array on bottom of a substrate for being surface mounted to an external PCB (Printed Circuit Board) thereby replacing conventional semiconductor package with leadframe acting as base, and slow transmissions because of overlong lead of leadframe won't happen. However, the BGA package cannot pass the MST level 1 (Moisture Sensitivity Test) all the time for which it is hard to deal moisture resistance since it has been developed, wherein MST is an international standard test such as published in JEDEC graded in 8 levels, level 1 has the most severe conditions.

FIG. 1 shows a conventional BGA package 100, which comprises a chip 110, a substrate 120, a molding compound 130 and a plurality of solder balls 140. The chip 110 is disposed on an upper surface 121 of the substrate 120 and electrically connected to the substrate 120 by utilizing a plurality of bonding wires 150. The molding compound 130 is substantially formed over the upper surface 121 of the substrate 120 only and a solder resist layer 123 is exposed on the lower surface 122 of the substrate 120. The solder balls 140 are bonded onto the lower surface 122 of the substrate 120. There is a problem that moisture will invade into product inside through the thin solder resist layer 123 located on the bottom of the substrate 120 to further cause product deficiencies like delamination or popcorn.

### SUMMARY

The primary object of the present invention is to provide a BGA package in order to solve the problems mentioned above, such as reducing exposed area of solder resist layer located on bottom of substrate to improve semiconductor product moisture resistance of BGA package, and preventing the solder balls from falling because of that the solder balls are pushed by the contact stress of the molding compound.

The secondary object of the present invention is to provide a BGA package, which prevents the molding compound located on the bottom of substrate from overflowing to and contaminating the ball pads of substrate by limiting the opening size of the solder resist layer on substrate.

The third object of the present invention is to provide a BGA package, which further prevents the solder balls from contacting the molding compound located on bottom of substrate.

One aspect of the present invention provides a BGA package with encapsulation on bottom of substrate, which comprises a chip, a substrate, a molding compound and a plurality of solder balls. The substrate is utilized to carry the chip and electrically connected to the chip. The substrate has an upper surface and a lower surface that forms a plurality of ball pads and a solder resist layer. The solder resist layer has a plurality of openings to expose at least the partial ball pads. The molding compound has a main body formed over the upper surface of the substrate and a molding cover layer formed over the lower surface of the substrate to encapsulate the solder resist layer. The molding cover layer has a plurality of through holes exposing the ball pads respectively and the through holes have a hole diameter greater than that of the openings of the solder resist layer in size. The solder balls are disposed in the through holes and are bonded to the exposed ball pads. This aspect is applied for various BGA packages.

Other aspects of the present invention can be applied to further solve the problems mentioned above.

With respect to the BGA package mentioned above, the openings of the solder resist layer are smaller than the ball pads in size.

With respect to the BGA package mentioned above, each of the through holes has an expanding mouth.

With respect to the BGA package mentioned above, the thickness of the molding cover layer is thinner than that of the main body of the molding compound and lower than height of the solder balls.

With respect to the BGA package mentioned above, the molding compound further has a lateral-connecting portion that is formed on an external surface between the upper and lower surfaces to connect the main body and the molding cover layer integrally.

With respect to the BGA package mentioned above, the chip is disposed on the upper surface of the substrate.

With respect to the BGA package mentioned above, the chip is disposed inside the substrate.

With respect to the BGA package mentioned above, it further comprises a plurality of electrical connection elements electrically connecting the chip to the substrate and formed inside the molding compound.

### DESCRIPTION OF THE DRAWINGS

FIG. 1 is a cross-sectional view of a known BGA package.

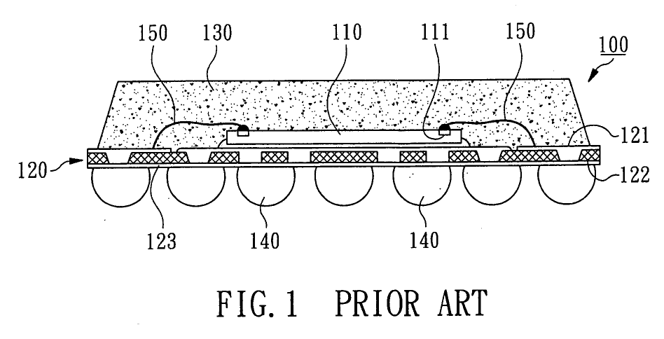

FIG. 2 is a cross-sectional view of a BGA package in accordance with the first embodiment of the present invention.

FIG. 3 is a cross-sectional view of a BGA package in accordance with the second embodiment of the present invention.

FIG. 4 is a cross-sectional view of a BGA package in accordance with the third embodiment of the present invention.

FIG. 5 is a cross-sectional view of a BGA package in accordance with the fourth embodiment of the present invention.

### DETAILED DESCRIPTION OF THE INVENTION

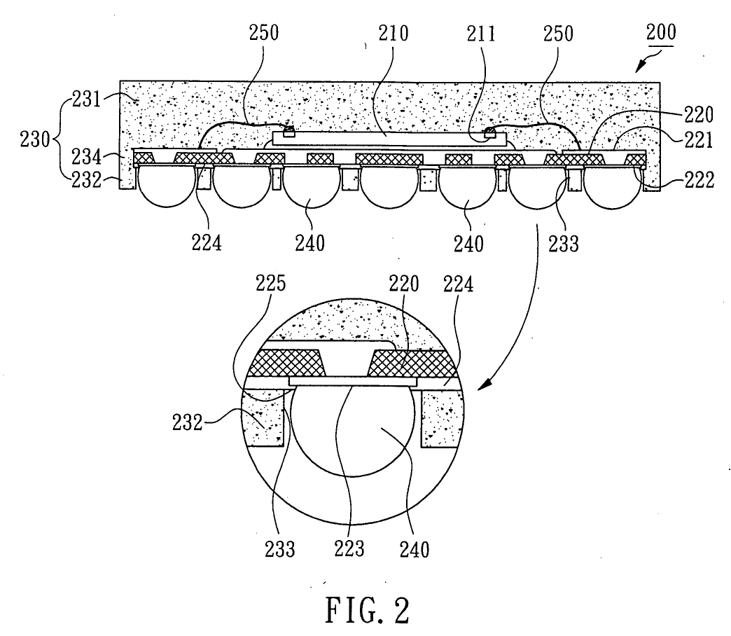

Referring to FIG. 2, therein is showed a BGA package in accordance with the first embodiment of the present invention. The package 200 comprises a chip 210, a substrate 220, a molding compound 230 and a plurality of solder balls 240. The chip 210 made of semiconductor material may be an IC chip having a plurality of bonding pads 211 on the active surface thereof.

The substrate 220 that is utilized to carry the chip 210 and electrically connected to the chip 210 has an upper surface 221 and a lower surface 222, a plurality of ball pads 223 and a solder resist layer 224 are formed on the lower surface 222. The substrate 220 may be a multi-layer printed circuit board (PCB) including BT resin, for example. In this embodiment, the rear surface of the chip 210 is attached to the upper surface 221 of the substrate 220 by applying a chip-attaching material and the bonding pads 211 on the chip 210 are electrically connected to the substrate 220 via a plurality of bonding wires acting as electrical connection elements 250 that are formed by wire-bonding method. Besides, the solder resist layer 224 has a plurality of openings 225 to expose at least the partial ball pads 223. In this embodiment, the ball pads 223 are solder-mask-defined (SMD) pads, the openings 225 of the solder resist layer 224 are smaller than the ball pads 223 in size to cover the peripheries of the ball pads 223.

The molding compound 230 is formed by molding method that applies upper and lower molds thereby obtaining excellent moisture resistance and electrical insulation. The molding compound 230 has a main body 231 and a molding cover layer 232. The main body 231 is formed over the upper surface 221 of the substrate 220 like general molding compound in shape to seal the chip 210 and the electrical connection elements 250 or the partial chip 210. The molding cover layer 232 is formed over the lower surface 222 of the substrate 220 to encapsulate most of the solder resist layer 224 and has a plurality of through holes 233 exposing the ball pads 223 respectively, that is to say, each of the through holes 233 only exposes a single ball pad 223. Additionally, the through holes 233 are greater than the openings 225 of the solder resist layer 224 in size. In this embodiment, the thickness of the molding cover layer 232 may be thinner than that of the main body 231 of the molding compound 230 and also lower than height of the solder balls 240. Moreover, the solder balls 240 are disposed in the through holes 233 and are bonded to the exposed ball pads 223 of the substrate 220.

Since the molding cover layer 232 would have excellent moisture resistance and is thicker than the solder resist layer 224 in thickness further covers on the solder resist layer 224 located at the bottom of the substrate 220 to prevent moisture invasion from the lower surface 222 of the substrate 220. Also, the solder balls 240 don't directly contact the through holes 233 of the molding cover layer 232 to avoid contact stress. Accordingly, the BGA package 200 can improve moisture resistance of semiconductor product even pass MST level 1 and prevent the solder balls 240 from falling because of that the solder balls 240 are pushed by contact stress of the molding compound 230 located on bottom of the substrate 220.

Since the openings 225 of the solder resist layer 224 are desirably smaller than the ball pads 223 in size, which present a SMD (Solder Mask Defined) pattern, the solder resist layer 224 at the surroundings of the openings 225 is higher than the exposed surface of the ball pads 223. Additionally, the size of the through holes 233 is slightly greater than that of the openings 225 of the solder resist layer 224, the molding compound 230 can be blocked not to overflow to and contaminate the ball pads 223 by the raised portions of the solder resist layer 224 around the openings 225.

Both the main body 231 of the molding compound 230 and the molding cover layer 232 should be made of same material and molded to form simultaneously. It is desirable that the molding compound 230 further has a lateral-connecting portion 234 formed on an external surface between the upper and lower surfaces 221 and 222 to integrally connect the main body 231 and the molding cover layer 232 thereby preventing moisture invasion to the external sides of the substrate 220.

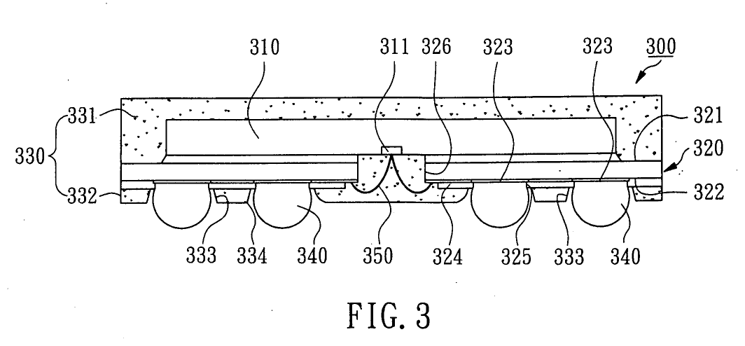

Furthermore, the present invention may be applied for various BGA package, such as the second embodiment showed in FIG. 3. A window type BGA package 300 comprises a chip 310, a printed circuit board 320, a molding compound 330 and a plurality of solder balls 340. A plurality of bonding pads 311 is formed on the active surface of the chip 310. The active surface of the chip 310 is attached to an upper surface 321 of the substrate 320. A lower surface 322 of the substrate 320 acting as a SMT surface on which the solder balls 340 are disposed. The substrate 320 further has a slot 326 and a plurality of electrical connection elements 350 such as bonding wires may pass through the slot 326 to electrically connect the bonding pads 311 of the chip 310 to the substrate 320. Besides, a plurality of ball pads 323 and a solder resist layer 324 are formed on the lower surface 322 of the substrate 320. The solder resist layer 324 has a plurality of openings 325 to expose at least a portion of the ball pads 323. The openings 325 of the solder resist layer 324 are smaller than the ball pads 323 in size to be SMD pads.

The molding compound 330 has a main body 331 and a molding cover layer 332, the main body 331 is formed over the upper surface 321 of the substrate 320 to protect the chip 310, and the molding cover layer 332 is formed over the lower surface 322 of the substrate 320 and the slot 326 to encapsulate most of the solder resist layer 324 and the electrical connection elements 350. The molding cover layer 332 has a plurality of through holes 333 exposing the ball pads 323 respectively and the hole diameter of the through holes 333 is greater than that of the openings 325 of the solder resist layer 324. Moreover, the solder balls 340 are disposed in the through holes 333 and are bonded to the exposed ball pads 323 of the substrate 320 thereby enhancing moisture resistance of BGA semiconductor products and preventing the solder balls 340 from falling because of that the solder balls 340 are pushed by contact stress of the molding compound 330 located on bottom of the substrate 320.

Preferably, each of the through hole 333 has an expanding mouth 334 to make the through holes 333 look like in outward stretch shape, so that the molding cover layer 332 can encapsulate the solder resist layer 324 as far as possible and prevents contact of the solder balls 340. In addition, the solder balls 340 are easily guided into the through holes 333 when the solder balls 340 are preformed before reflowing

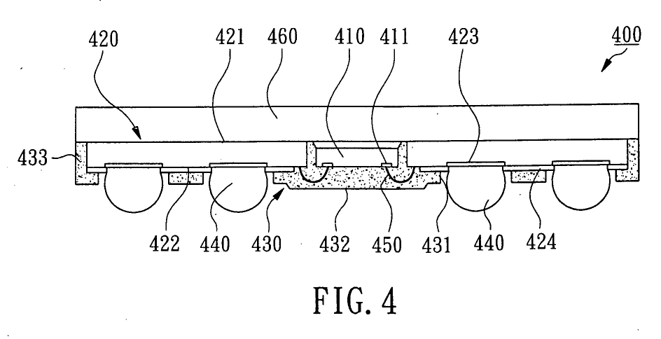

FIG. 4 shows a cavity-down BGA package 400 in the third embodiment of the present invention, comprises a chip 410, a substrate 420, a molding compound 430, a plurality of solder balls 440 and further a thermal spreader 460 for disposing the substrate 420 and the chip 410. The chip 410 is disposed on the thermal spreader 460 through an opening of the substrate 420 that is meant the chip 410 is disposed inside the substrate 420. The substrate 420 has an upper surface 421 and a lower surface 422, and has a plurality of ball pads 423 and a solder resist layer 424 formed on the lower surface 422 of the substrate 420. Therein, the upper surface 421 is attached to the thermal spreader 460, A plurality of electrical connection elements 450 such as bonding wires are utilized to electrically connect the bonding pads 411 on the chip 410 to the substrate 420.

The molding compound 430 has a protrusion 432 as a main body to seal the chip 410 and the electrical connection elements 450. The molding compound 430 further has a molding cover layer extending over the lower surface 422 of the substrate 420 to encapsulate most of the solder resist layer 424. The molding compound 430 has a plurality of through holes 431 exposing the ball pads 423 respectively. In general, each through hole 431 has a hole diameter approximately as same as diameter of the corresponding solder ball 440 but allows the through holes 431 not to contact the solder balls 440. Moreover, the solder balls 440 are disposed in the through holes 431 and are bonded to the exposed ball pads 423 of the substrate 420 thereby improving moisture resistance of BGA semiconductor products and avoiding the solder balls 440 from falling because of that the solder balls 440 are not pushed by contact stress of the molding compound 430 located on bottom of the substrate 420. In this embodiment, the molding compound 430 further has a lateral-connecting portion 433 that is substantially formed on an external surface of the substrate 420 to prevent moisture invasion from the sides of the substrate 420.

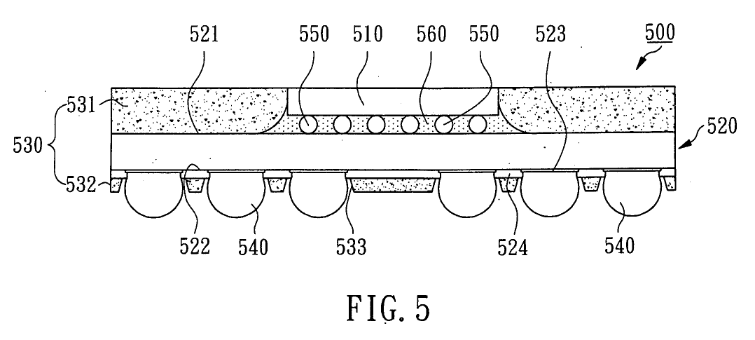

In the fourth embodiment of the present invention, as showed in FIG. 5, a flip-chip BGA package 500 mainly comprises a chip 510, a substrate 520, a molding compound 530 and a plurality of solder balls 540. The chip 510 is disposed on an upper surface 521 of the substrate 520 by utilizing flip-chip mounting method and a plurality of bumps acting as electrical connection elements 550 electrically connect the chip 510 to the substrate 520 during flip-chip mounting process. It is able to further seal the electrical connection elements 550 with an underfilling material 560. A lower surface 522 of the substrate 520 acts as a SMT surface to dispose the solder balls 540. Furthermore, a plurality of ball pads 523 and a solder resist layer 524 are formed on the lower surface 522 of the substrate 520. The molding compound 530 has a main body 531 and a molding cover layer 532, the main body 531 is formed over the upper surface 521 of the substrate 520 and has a same size with the substrate 520 so as to protect the chip 510 and prevent periphery of the substrate 520 from transforming and warpage, and the molding cover layer 532 is formed over the lower surface 522 of the substrate 520 to encapsulate most of the solder resist layer 524. Also, the molding cover layer 532 has a plurality of through holes 533 aligned with openings of the solder resist layer 524 to expose the solder balls 540 respectively. The through holes 533 have a hole diameter greater than that of the openings of the solder resist layer 524. Moreover, the solder balls 540 are disposed in the through holes 533 and are bonded to the exposed ball pads 523 of the substrate 520, so that moisture resistance of BGA semiconductor products can be significantly improved and the solder balls 540 can also be protected from falling due to pushed by stress.

While the present invention has been particularly illustrated and described in detail with respect to the preferred embodiments thereof, it will be clearly understood by those skilled in the art that various changed in form and details may be made without departing from the spirit and scope of the present invention.

What is claimed is:

1. A BGA package comprising:
a chip;
a substrate carrying the chip and electrically connected to the chip, the substrate having an upper surface, a lower surface, a plurality of ball pads and a solder resist layer formed on the lower surface, wherein the solder resist layer has a plurality of openings to expose at least some portions of the ball pads;
a molding compound having a main body and a molding cover layer, the main body being formed over the upper surface of the substrate, the molding cover layer being formed over the lower surface of the substrate to encapsulate the solder resist layer and having a plurality of through holes exposing the ball pads respectively, the through holes having a hole diameter greater than that of the openings of the solder resist layer; and
a plurality of solder balls disposed in the through holes respectively and bonded to the exposed ball pads of the substrate.

2. The BGA package in accordance with claim 1, wherein the diameter of the openings of the solder resist layer is smaller than that of the ball pads.

3. The BGA package in accordance with claim 1, wherein each of the through holes has an expanding mouth.

4. The BGA package in accordance with claim 1, wherein the thickness of the molding cover layer is thinner than that of the main body of the molding compound and lower than height of the solder balls.

5. The BGA package in accordance with claim 1, wherein the molding compound further has a lateral-connecting portion that is formed on an external surface between the upper and lower surfaces of the substrate and integrally connects the main body and the molding cover layer.

6. The BGA package in accordance with claim 1, wherein the chip is disposed on the upper surface of the substrate.

7. The BGA package in accordance with claim 1, wherein the chip is disposed inside the substrate.

8. The BGA package in accordance with claim 1, further comprising a plurality of electrical connection elements electrically connecting the chip to the substrate and formed inside the molding compound.

9. A BGA package comprising:
a chip;
a substrate having an upper surface, a lower surface and a plurality of ball pads on the lower surface;
a molding compound encapsulating at least a portion of the chip and the lower surface of the substrate and having a plurality of exposed ball pads; and
a plurality of solder balls bonded to the ball pads through the through holes and electrically connected to the chip by the substrate, wherein the through holes have a hole diameter greater than the diameter of the solder balls to allow the solder balls not to contact the molding compound.

10. The BGA package in accordance with claim 9, wherein the hole diameter of the through holes is approximately as same as the diameter of the corresponding solder balls.

11. The BGA package in accordance with claim 9, wherein each of the through holes has an expanding mouth.

12. The BGA package in accordance with claim 9, wherein the molding compound further has a lateral-connecting portion that is formed on an external surface of the substrate between the upper surface and the lower surface.

13. The BGA package in accordance with claim 9, further comprising a thermal spreader to dispose the substrate and the chip.

14. The BGA package in accordance with claim 9, further comprising a plurality of electrical connection elements electrically connecting the chip to the substrate and encapsulated by the molding compound.

15. The BGA package in accordance with claim 14, wherein the electrical connection elements include a plurality of bonding wires.

16. The BGA package in accordance with claim 14, wherein the electrical connection elements include a plurality of bumps.
